(19) United States
(12) Patent Application Publication
(10) Pub. No.: US 2006/0226870 A1
(43) Pub. Date: Oct. 12, 2006

(54) CONTROL CIRCUIT FOR PROVIDING COMMAND SIGNALS TO A CLOCK GENERATOR

(75) Inventor: Kun Le, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Tu-Cheng (TW)

(21) Appl. No.: 11/160,686

(22) Filed: Jul. 5, 2005

(30) Foreign Application Priority Data
Apr. 1, 2005 (CN) 200510033929.5

(51) Int. Cl. H03K 19/003

(52) U.S. Cl. 326/33

(57) ABSTRACT

A control circuit for providing command signals to a clock generator includes: a voltage input terminal, a voltage output terminal, a voltage control terminal, a transistor, a first resistor, and a second resistor. The first and second resistors are connected in series between the voltage input terminal and ground. The transistor has a base connected to a node between the first and second resistors, an emitter coupled to the voltage control terminal, and a collector coupled to the voltage input terminal and also coupled to the voltage output terminal. The voltage output terminal outputs the command signal to the clock generator. The control circuit needs no further transistor, and is relatively inexpensive.

### FIELD OF THE INVENTION

The present invention relates to a control circuit, and particularly to a control circuit for providing command signals to a clock generator.

### DESCRIPTION OF RELATED ART

A clock generator located on a motherboard of a computer is used to generate clock signals. A working status of the clock generator is controlled by a command signal VTT_PWRGD, which is outputted by a control circuit. When the command signal VTT_PWRGD is at a high level, the clock generator is at an on-working status. When the command signal VTT_PWRGD is at a low level, the clock generator is at an off-working status.

FIG. 1 shows a conventional control circuit for providing command signals to a clock generator, which is applied to a motherboard installed with an Intel 865/915 chipset. The control circuit includes transistors Q1, Q2. The transistor Q1 has a base B1 connected to a voltage control terminal Vccp via a resistor R3, and a collector C1 connected to a voltage input terminal Vdc via a resistor R1 and also connected to a base B2 of the transistor Q2. A collector C2 of the transistor Q2 is connected to a voltage output terminal VTT_PWRGD, which outputs the command signals to the clock generator. A 3.3 volt voltage of the voltage input terminal Vdc is provided by a motherboard power supply. As a control terminal, the voltage control terminal Vccp has a control voltage ranging from 1.1 volts to 1.55 volts when the control voltage is inputted from another part of the motherboard circuit, and a zero volt voltage when the control voltage is not inputted. When the control voltage of the voltage control terminal Vccp is inputted, the transistor Q1 is turned on so a voltage of the collector C1 of the transistor Q1 drops to a low level, and the transistor Q2 is thereby turned off so the voltage output terminal VTT_PWRGD rises to a high level. When the control voltage of the voltage control terminal Vccp is not inputted, the transistor Q1 is turned off so the voltage of the collector C1 of the transistor Q1 rises to a high level, and the transistor Q2 is thereby turned on so the voltage output terminal VTT_PWRGD drops to a low level.

The cost of producing the circuit is an important consideration for manufacturers and circuit designers alike. If the circuit design of the motherboard can be configured with fewer transistor components and still achieve the same function, the circuit can be produced at a lower cost.

What is needed, therefore, is a control circuit for providing command signals to a clock generator, which control circuit uses fewer transistor components and achieves reduced costs.

### SUMMARY OF INVENTION

A control circuit is provided for offering command signals to a clock generator, the control circuit having a simple design and low cost. In a preferred embodiment, the control circuit includes a voltage input terminal, a voltage output terminal, a voltage control terminal, a transistor, a first resistor, and a second resistor. The first and second resistors are connected in series between the voltage input terminal and ground. The transistor has a base connected to a node between the first and second resistors, an emitter coupled to the voltage control terminal, and a collector coupled to the voltage input terminal and also coupled to the voltage output terminal. The voltage output terminal outputs the command signal to the clock generator. It is of advantage that the control circuit omits the need for another transistor that is normally required in a conventional control circuit. This reduces the cost of the control circuit while assuring full functionality of the control circuit.

Other advantages and novel features will become more apparent from the following detailed description when taken in conjunction with the accompanying drawings, in which:

### BRIEF DESCRIPTION OF DRAWINGS

FIG. 1 is a circuit diagram of a conventional control circuit for providing command signals to a clock generator; and

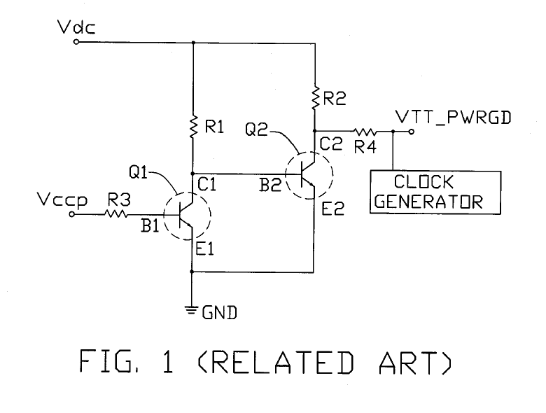

FIG. 2 is a circuit diagram of a control circuit for providing command signals to a clock generator, in accordance with a preferred embodiment of the present invention.

### DETAILED DESCRIPTION

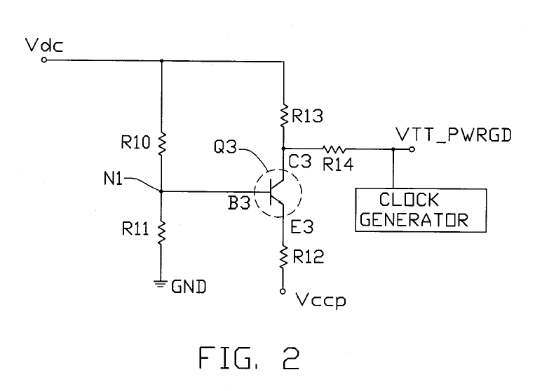

FIG. 2 shows a control circuit for providing command signals to a clock generator, in accordance with a preferred embodiment of the present invention. The control circuit includes a transistor Q3, a voltage sampling circuit including a first resistor R10 and a second resistor R11, a third resistor R12, a fourth resistor R13, a fifth resistor R14, a voltage input terminal Vdc, a voltage output terminal VTT_PWRGD, and a voltage control terminal Vccp. The first resistor R10 and the second resistor R11 are connected in series between the voltage input terminal Vdc and a ground source GND. A node N1 between the first resistor R10 and the second resistor R11 is connected to a base B3 of the transistor Q3, for offering a sampling voltage to the base B3. The transistor Q3 has an emitter E3 connected to the voltage control terminal Vccp via the third resistor R12, and a collector C3 connected to the voltage input terminal Vdc via the fourth resistor R13 and also connected to the voltage output terminal VTT_PWRGD via the fifth resistor R14. The third resistor R12 and the fourth resistor R13 are used to limit current flowing to the transistor Q3. The fifth resistor R14 is used to limit current flowing to the voltage output terminal VTT_PWRGD.

When the control voltage of the voltage control terminal Vccp is applied, the voltage difference between the base B3 and the emitter E3 is less than a turnover voltage of the transistor Q3, so the transistor Q3 is turned off. At this status, the voltage of the voltage output terminal VTT_PWRGD is equal to the voltage of the voltage input terminal Vdc; that is, the voltage of the voltage output terminal VTT_PWRGD is at a high level.

When the control voltage of the voltage control terminal Vccp is not applied, the voltage difference between the base B3 and the emitter E3 is greater than a turnover voltage of the transistor Q3, so the transistor Q3 is turned on. The relationship between a voltage Vout of the voltage output terminal VTT_PWRGD and a voltage Vin of the voltage input terminal Vdc is as follows: Vout=(R12*Vin)/(R12+R13)

To make the voltage Vout be at a low level, a resistance value of the fourth resistor R13 needs to be greater than a resistance value of the third resistor R12. For example, when the fourth resistor R13 is 10 Kohms, the third resistor R12 is 330 ohms, and the Vin is 3.3 volts, then the voltage output terminal VTT_PWRGD outputs a 0.1 volt voltage.

The values of the resistors R10 and R11 should be properly assigned to make the transistor Q3 reliably be turned off when the control voltage of the voltage control terminal Vccp is applied. As mentioned above, the control voltage ranges from 1.1 volts to 1.55 volts when the control voltage is applied. If only the transistor Q3 is turned off when the control voltage is 1.1 volts, the transistor Q3 is turned off when the control voltage ranges from 1.1 volts to 1.55 volts. Therefore the values of the resistors R10 and R11 are assigned to make the voltage difference between the base B3 and the emitter E3 be less than the turnover voltage of the transistor Q3 when the control voltage is 1.1 volts.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A control circuit for providing command signals to a clock generator, the control circuit comprising:
a voltage input terminal for receiving an input voltage;
a voltage output terminal for outputting the command signals to the clock generator;
a voltage control terminal for receiving a control voltage;
a first resistor and a second resistor being connected in series between the voltage input terminal and ground; and
a transistor having a base, an emitter and a collector, the base being connected to a node between the first resistor and the second resistor, the emitter being coupled to the voltage control terminal, and the collector being coupled to the voltage input terminal and also coupled to the voltage output terminal.

2. The control circuit as claimed in claim 1, further comprising a third resistor being connected between the emitter of the transistor and the voltage control terminal.

3. The control circuit as claimed in claim 2, further comprising a fourth resistor being connected between the collector of the transistor and the voltage input terminal.

4. The control circuit as claimed in claim 3, further comprising a fifth resistor being connected between the collector of the transistor and the voltage output terminal.

5. The control circuit as claimed in claim 1, wherein the input voltage of the voltage input terminal is a 3.3 volt direct current voltage.

6. The control circuit as claimed in claim 1, wherein the values of the first resistor and the second resistor are assigned to make the transistor be turned off when the control voltage of the voltage control terminal is applied.

7. A control circuit for providing command signals to a clock generator, the control circuit comprising:
a voltage input terminal for receiving an input voltage;
a voltage output terminal for outputting the command signals to the clock generator;
a voltage control terminal for receiving a control voltage;
a transistor having a base, an emitter and a collector, the emitter being coupled to the voltage control terminal, the collector being coupled to the voltage input terminal and also coupled to the voltage output terminal; and
a voltage sampling circuit being connected between the voltage input terminal and ground for offering a sampling voltage to the base of the transistor.

8. The control circuit as claimed in claim 7, wherein the voltage sampling circuit comprises a first resistor and a second resistor connected in series, the base of the transistor being connected to a node between the first resistor and the second resistor.

9. The control circuit as claimed in claim 7, further comprising a third resistor being connected between the emitter of the transistor and the voltage control terminal.

10. The control circuit as claimed in claim 9, further comprising a fourth resistor being connected between the collector of the transistor and the voltage input terminal.

11. The control circuit as claimed in claim 10, further comprising a fifth resistor being connected between the collector of the transistor and the voltage output terminal.

12. The control circuit as claimed in claim 7, wherein the input voltage of the voltage input terminal is a 3.3 volt direct current voltage.

13. The control circuit as claimed in claim 8, wherein the values of the first resistor and the second resistor are assigned to make the transistor be turned off when the control voltage of the voltage control terminal is applied.
